(19) United States
(12) Patent Application Publication
(10) Pub. No.: US 2026/0201543 A1
(43) Pub. Date: Jul. 16, 2026

(54) PHYSICAL VAPOR DEPOSITION (PVD) HAVING A HIGH DEPOSITION RATE WITHOUT COMPROMISING FILM STRESS MITIGATION

(71) Applicant: Taiwan Semiconductor Manufacturing Company, Ltd., Hsinchu (TW)

(72) Inventors: Yen-Liang Lin, Yilan (TW); Chin-I Wang, Tainan (TW); Yu Chi Liu, Taichung (TW)

(21) Appl. No.: 19/019,381

(22) Filed: Jan. 13, 2025

(51) Int. Cl. C23C 14/35; C23C 14/50

(52) U.S. Cl. CPC C23C 14/35; C23C 14/50

(57) ABSTRACT

A physical vapor deposition (PVD) system is provided. The PVD system includes: a chamber body enclosing a processing region; a substrate support disposed in the chamber body and configured to support a substrate; a PVD target disposed in the chamber body and over the substrate support; a radio frequency (RF) coil disposed in the chamber body, the RF coil being above the substrate support and below the PVD target; a first direct current (DC) power supply electrically coupled to the PVD target to provide a DC bias to the PVD target; and an alternating current (AC) power supply electrically coupled to the RF coil, wherein the AC power supply delivers RF power to the RF coil to generate an electromagnetic field in the processing region.

### FIELD

Embodiments of the present disclosure relate generally to physical vapor deposition (PVD), and more particularly a PVD system using RF sputtering in addition to DC sputtering.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area.

While some integrated device manufacturers (IDMs) design and manufacture integrated circuits (IC) themselves, fabless semiconductor companies outsource semiconductor fabrication to semiconductor fabrication plants or foundries. Semiconductor fabrication consists of a series of processes in which a device structure is manufactured by applying a series of layers onto a substrate. This involves the deposition and removal of various dielectric, semiconductor, and metal layers. The areas of the layer that are to be deposited or removed are controlled through photolithography. Each deposition and removal process is generally followed by cleaning as well as inspection steps. Therefore, both IDMs and foundries rely on numerous semiconductor equipment and semiconductor fabrication materials, often provided by vendors. There is always a need for customizing or improving those semiconductor equipment and semiconductor fabrication materials, which results in more flexibility, reliability, and cost-effectiveness.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating an example PVD system in accordance with some embodiments.

FIG. 2 is a diagram illustrating different distribution of ions at different RF frequencies in accordance with some embodiments.

FIG. 3 is a diagram illustrating the substrate bow measures at different RF power in accordance with some embodiments.

FIG. 4A is a diagram illustrating the film morphology of a film deposited using pure sputtering.

FIG. 4B is a diagram illustrating the film morphology of a film deposited using pure sputtering plus RF sputtering in accordance with some embodiments.

FIG. 5 is a diagram illustrating an example PVD system according to some embodiments.

FIG. 6A is a cross-sectional diagram illustrating an example magnet assembly in accordance with some embodiments.

FIG. 6B is a diagram illustrating a top view of the example magnet assembly shown in FIG. 6A in accordance with some embodiments.

FIG. 6C is a diagram illustrating a simulation result of the example magnet assembly shown in FIG. 6A in accordance with some embodiments.

FIG. 6D is a diagram illustrating another example magnet assembly in accordance with some embodiments.

FIG. 7 is a flowchart illustrating an example method for operating a PVD system in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

Physical vapor deposition (PVD) is a common process for depositing a film of material on a substrate and is commonly used in semiconductor fabrication. The PVD process is carried out at a high vacuum in a chamber containing a substrate (e.g., a wafer) and a solid source or slab of the material (i.e., a “PVD target” or simply a “target”) to be deposited on the substrate. In the PVD process, the PVD target is physically converted from a solid into a vapor. The vapor of the target material is transported from the PVD target to the substrate, where it is condensed on the substrate as a film.

There are many methods for accomplishing PVD, including evaporation, e-beam evaporation, plasma spray deposition, and sputtering. Among those methods, sputtering is usually the most frequently used method for accomplishing PVD. During sputtering, gas plasma is created in the chamber and directed to the PVD target. The plasma physically dislodges or erodes (sputters) atoms or molecules from the reaction surface of the PVD target into a vapor of the target material, as a result of a collision with high-energy particles (e.g., ions) of the plasma. The vapor of sputtered atoms or molecules of the target material is transported to the substrate through a region of reduced pressure and condenses on the substrate, forming the film of the target material.

Intrinsic stress gradients in semiconductor processing refer to variations in stress within a material that arise from the manufacturing process itself, rather than external factors like mechanical loading or temperature changes.

These gradients can significantly impact the performance and reliability of semiconductor devices. High stress levels can lead to device failure, such as gate oxide breakdown or junction leakage. Stress can promote the formation of defects, such as dislocations or stacking faults, which can degrade device performance. In extreme cases, stress gradients can cause the semiconductor wafer to warp or bow, making it difficult to fabricate devices with precise dimensions.

Causes of intrinsic stress gradients include, among other causes, PVD (e.g., sputtering), ion implantation (the implantation of ions into the semiconductor lattice can induce localized stress due to the atomic displacements and lattice damage), chemical vapor deposition (CVD) (the deposition of thin films can introduce stress due to differences in the thermal expansion coefficients of the film and the substrate, as well as the deposition conditions), etching (wet or dry etching processes can create stress gradients due to the removal of material and the formation of surface features), thermal processing (heating and cooling cycles during annealing or other thermal treatments can cause stress variations due to differential thermal expansion).

As to PVD and specifically sputtering, intrinsic stress gradients primarily arise from the following factors: the evolution of the metal film during nucleation, coalescence and thickening during the sputtering process. Coalescence is the process where small, isolated features or particles merge or grow together to form larger structures. In PVD and specifically sputtering, small, isolated islands of material can merge to form a continuous film. This is sometimes referred to as “island coalescence.” Particles suspended in the plasma can coalesce, leading to surface roughness or contamination. This is sometimes referred to as “particle coalescence.” For thick (e.g., 500 nm or above) metal film, stress gradients can develop across the thickness of the film due to variations in deposition conditions or substrate temperature. Accordingly, peeling, chuck failure, or wafer brooding during the process may occur.

Previous efforts to reduce intrinsic stress gradient have focused on heat treatment during or after film deposition or the modification of process power. For example, stress-relieving anneals have been employed to reduce residual stress in the material. However, stress-relieving anneals are not always appropriate. In some cases, only low temperature deposition is acceptable for thermal budget considerations, such as avoiding film crystallization. In addition, extra cost could be incurred for stress mitigation measures during the deposition.

Moreover, both pure direct current (DC) sputtering and pure radio frequency (RF) sputtering have deficiencies. In a pure DC sputtering process, a DC voltage is applied between a negatively charged target and a positively charged substrate. This creates a plasma of ionized gas between the target and substrate. The plasma generation is called direct ionization. Positive ions in the plasma bombard the target, causing material to be ejected and deposited onto the substrate. Pure DC sputtering is relatively simple, relatively inexpensive, suitable for sputtering conductive materials. Importantly, pure DC sputtering can offer high deposition rates. However, pure DC sputtering cannot be used to sputter insulating materials due to the buildup of charge on the charge and can lead to target erosion and uneven deposition. More importantly, Pure DC sputtering typically results in compressive film stress.

In a pure RF sputtering process, on the other hand, an alternating current (AC) voltage is applied to a capacitively coupled system, creating a plasma of ionized gas. The plasma generation is called capacitive ionization. The plasma is sustained by the oscillating electric field. The target and substrate are both exposed to the plasma, allowing for the sputtering of both conductive and insulating materials. Pure RF sputtering provides better control over plasma parameters. Additionally, target erosion can be minimized. However, pure RF sputtering has a more complex setup and higher operating costs. Importantly, the deposition rate is not as high as that of DC sputtering.

Thus, there is a need for improving pure DC sputtering and pure RF sputtering, especially when a low deposition temperature is required.

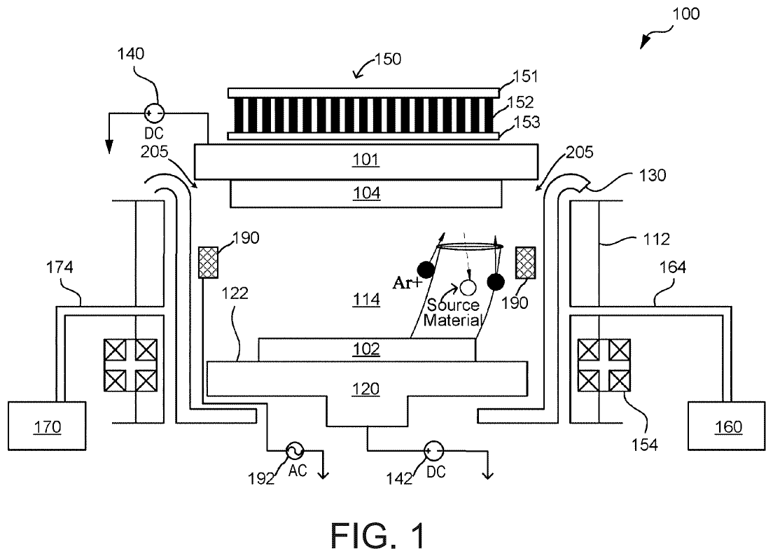

In accordance with some aspects of the disclosure, a PVD system is provided. The PVD system uses RF sputtering in addition to DC sputtering, and the RF frequency is fine-tuned to maintain a comparable deposition rate, as compared to pure DC sputtering, without compromising the film stress. On the other hand, a strong magnet assembly that produces a high magnetic field strength can increase the ionization efficiency of the gas, leading to a higher density of ions in the plasma. Also, a strong magnetic field can trap ions within the plasma, increasing their residence time and the likelihood of them striking the target. These factors contribute to a higher deposition rate. As to the film stress, a strong magnetic field can influence the energy and direction of the sputtered atoms, leading to a more relaxed film structure. Details of these techniques will be discussed below in greater detail with reference to FIGS. 1-7.

FIG. 1 is a schematic diagram illustrating an example PVD system 100 in accordance with some embodiments. The PVD system 100 is capable of depositing a film onto a substrate 102 using a PVD target 104. During the PVD process, the PVD target 104 is bombarded by energetic ions of plasma, causing material to be knocked off the PVD target 104 and deposited as a film on the substrate 102.

In some embodiments, the PVD system 100 is a magnetron PVD system including a chamber body 112, which encloses a processing region or a plasma zone 114. A substrate support 120 is disposed within the chamber body 112. The substrate support 120 has a substrate receiving surface 122 that receives and supports the substrate 102 during the PVD process, so that a surface of the substrate 102 is opposite to the front surface of the PVD target 104 that is exposed to the processing region 114. In some embodiments, the substrate support 120 is composed of aluminum, stainless steel, or ceramic material. In some embodiments, the substrate support 120 is an electrostatic chuck that includes a dielectric material. The PVD target 104 is disposed on a lid 101.

The substrate support 120 is electrically conductive and is electrically coupled to a DC power supply (e.g., a DC power supply circuit) 142. The lid 101 is electrically conductive and is electrically coupled to another DC power supply (e.g., a DC power supply circuit) 140. Since a backing plate of the PVD target 104 is electrically coupled to the lid 101, the DC power supply 140 is electrically coupled to the backing plate of the PVD target. In one embodiment, the DC power supply 140 provides a negative DC bias, whereas the DC power supply 142 provides a positive DC bias. In other words, the power supply 140 is configured to negatively bias the PVD target 104 with respect to the chamber body 112, whereas the power supply 142 is configured to positively bias the substrate support 120, exciting a plasma-forming gas, for example, argon (Ar), into a plasma. Additionally, positive ions are attracted to and bombard the PVD target 104 due to the electrical field between the PVD target 104 and the substrate 102 generated by the DC power supply 140 and the DC power supply 142.

A shield 130, also referred to as a “dark space shield,” is positioned inside the chamber body 112 and proximate sidewalls 205 of the PVD target 104 to protect inner surfaces of the chamber body 112 and sidewalls 205 of the PVD target 104 from unintended deposition. The shield 1 30 is positioned very close to the sidewalls 205 to minimize re-sputtered material from being deposited thereon. The shield 130 has a plurality of apertures (not shown) defined therethrough for admitting a plasma-forming gas such as argon (Ar) from the exterior of the shield 130 into its interior.

The PVD system 100 also includes an RF coil 190 and an AC power supply (e.g., an AC power supply circuit) 192. The RF coil 190 is configured to generate the electromagnetic field that sustains the plasma and drives the sputtering process. Specifically, the RF coil 190 applies an alternating current (AC) voltage to the RF electrodes. This AC voltage creates an oscillating electric field that ionizes the gas, thereby forming a plasma. From a power coupling perspective, the RF coil 190 efficiently couples RF power, provided by the RF power supply 192, into the plasma, thereby providing the energy needed for sputtering. The oscillating electric field also causes positive ions (e.g., argon ions) in the plasma to accelerate toward the negatively biased PVD target 104. When these positive ions strike the PVD target 104, they cause material to be ejected and deposited onto the substrate 102.

In some embodiments, the RF coil 190 is a planar RF coil. In some examples, the planar RF coil 190 consists of a flat and circular (or alternatively rectangular) conductor placed parallel to the PVD target 104. In other embodiments, the RF coil 190 is a helical RF coil. In some examples, the helical RF coil 190 has a spiral shape and can provide more uniform plasma distribution and better power coupling efficiency. It should be understood that these examples are not intended to be limiting. One of ordinary skill in the art would recognize many variations, modifications, and alternatives.

In some embodiments, the RF frequency used by the AC power supply 192 is equal to or higher than 8 MHz. In some embodiments, the RF frequency used by the AC power supply 192 is between 13.5 MHz and 100 MHz. In some embodiments, the RF frequency used by the AC power supply 192 is between 13.5 MHz and 50 MHz. The choice of frequency can affect plasma characteristics and deposition rates. An appropriate RF frequency can be employed depending on the specific design conditions of the PVD system 100. One of ordinary skill in the art would recognize many variations, modifications, and alternatives.

The AC power supply 192 delivers power through the RF coil 190. The delivered power (typically in the range of kilowatts to tens of kilowatts) determines the sputtering rate and plasma density. Higher power levels can lead to increased deposition rates but may also cause target overheating or plasma instabilities. Therefore, the power level is fine-tuned to achieve the best tradeoff between the deposition rates and plasma stabilities. Moreover, to ensure efficient power transfer from the AC power supply 192 to the RF coil 190, a matching network is often used to impedance match the components. In some embodiments, the AC power supply 192 comprises solid-state power supplies, which utilize, for example, MOSFETs to generate the RF power. In some embodiments, the AC power supply 192 comprises tube amplifiers, which utilize, for example, vacuum tubes to generate the RF power. One of ordinary skill in the art would recognize many variations, modifications, and alternatives.

A magnet assembly 150 is disposed above the PVD target 104 and the lid 101. The magnet assembly 150 is configured to project a magnetic field parallel to the front surface of the PVD target 104 to trap electrons, thereby increasing the density of the plasma and increasing the sputtering rate. In some embodiments, the magnet assembly 150 is configured to scan about the back of the PVD target 104 to improve the uniformity of deposition.

In some embodiments, the magnet assembly 150 is characterized by a high surface magnetic field strength (e.g., equal to or larger than 400 Gs), thereby further improving the deposition rate without compromising the stress mitigation. A strong magnet assembly 150 that produces a high magnetic field strength can increase the ionization efficiency of the gas, leading to a higher density of ions in the plasma. This can result in a higher deposition rate due to increased bombardment of the target material. Also, a strong magnetic field can trap ions within the plasma, increasing their residence time and the likelihood of them striking the target. This can also contribute to a higher deposition rate. As to the film stress, a strong magnetic field can influence the energy and direction of the sputtered atoms, leading to a more relaxed film structure.

In some embodiments and as shown in FIG. 1, the magnet assembly 150 also includes a side electromagnet 154 around the chamber body 112. One of ordinary skill in the art would recognize many variations, modifications, and alternatives.

As will be described in greater detail below, the magnet assembly 150 shown in FIG. 1, in this embodiment, includes a bottom support structure 153, a top support structure 151, and a number of magnetic columns (or “magnetic pillars”) 152 disposed between them. The magnet assembly 150 can provide a stronger magnetic field in the processing region or a plasma zone 114.

A gas source 160 is in fluidic combination with the chamber body 112 via a gas supply pipe 164. The gas source 160 is configured to supply a plasma-forming gas to the process region 114 via the gas supply pipe. The plasm-forming gas is an inert gas and does not react with the materials in the PVD target 104. In some embodiments, the plasma-forming gas includes argon (Ar), xenon (Xe), neon (Ne), or helium (He), which is capable of energetically impinging upon and sputtering source material (and the dopant in some embodiments) from the PVD target 104. In some embodiments, the gas source 160 is also configured to supply a reactive gas into the PVD system 100. The reactive gas includes one or more of an oxygen-containing gas, a nitrogen-containing gas, a methane-containing gas, that is capable of reacting with the sputtering source material in the PVD target 104 to form a layer on the substrate 102.

A vacuum device 170 is in fluidic communication with the PVD system 100 via an exhaust pipe 174. The vacuum device 170 is used to create a vacuum environment in the PVD system 100 when needed during the PVD process. In some embodiments, the PVD system 100 has a pressure in a range from about 1 mTorr to about 10 Torr. The spent process gases and byproducts are exhausted from the PVD system 100 through the exhaust pipe 174.

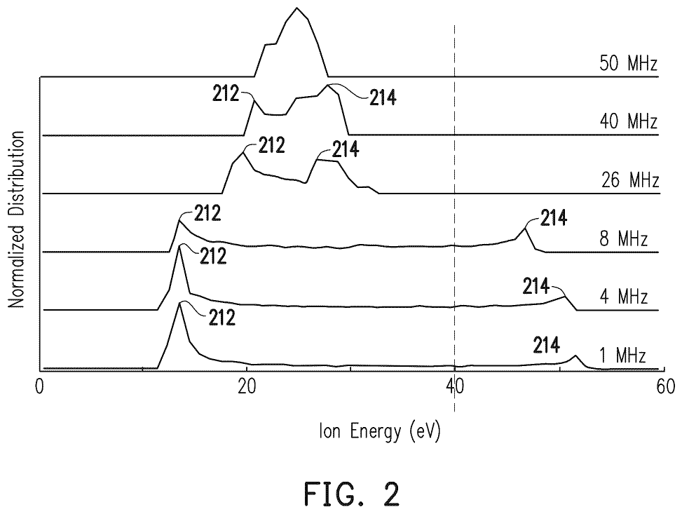

FIG. 2 is a diagram illustrating different distributions of ions at different RF frequencies in accordance with some embodiments. It has been appreciated by Applicant that the ions generated in the processing region or a plasma zone 114 are characterized by an ion energy distribution pattern. When the RF frequency is relatively low (e.g., 1 MHz, 4 MHz, or 8 MHz), the ion energy distribution curve is characterized by a lower peak 212 and an upper peak 214 distant from each other. The upper peak 214 at a relatively low RF frequency is above 40 eV.

It has been observed that high ion energy can lower the deposition rate for several reasons. First, when ions strike the deposited film with high energy, they can cause atoms from the film to be ejected back into the vacuum chamber. This process, known as resputtering, reduces the net deposition rate. Second, high-energy ions can damage the deposited film by creating defects such as vacancies, interstitials, and dislocations. These defects can interfere with the growth process and reduce the deposition rate. Third, high ion energies can promote gas-phase reactions between the sputtered atoms and the surrounding gas molecules. These reactions can form compounds that do not condense onto the substrate, reducing the deposition rate. Fourth, high ion energies can heat the substrate, leading to increased thermal desorption of the deposited atoms. This can reduce the deposition rate, especially for materials with low melting points. Fifth, in certain cases, high ion energies can cause the target material to be eroded at a faster rate than the deposition rate, leading to a net decrease in film thickness.

Thus, it has been appreciated by Applicant that suppressing the upper peak 214 would increase the deposition rate. As shown in FIG. 2, as the RF frequency increases (e.g., 26 MHz, 40 MHz, 50 MHz), the upper peak 214 shifts toward a lower ion energy region (e.g., below 40 eV). When the RF frequency reaches 50 MHz, the lower peak 212 and the upper peak 214 almost merge. As such, by increasing the RF frequency applied to the RF coil 190, the upper peak 214 is suppressed and shifted to a lower ion energy region, and the percentage of ions with an energy higher than 40 eV is reduced significantly. Therefore, the deposition rate can be increased.

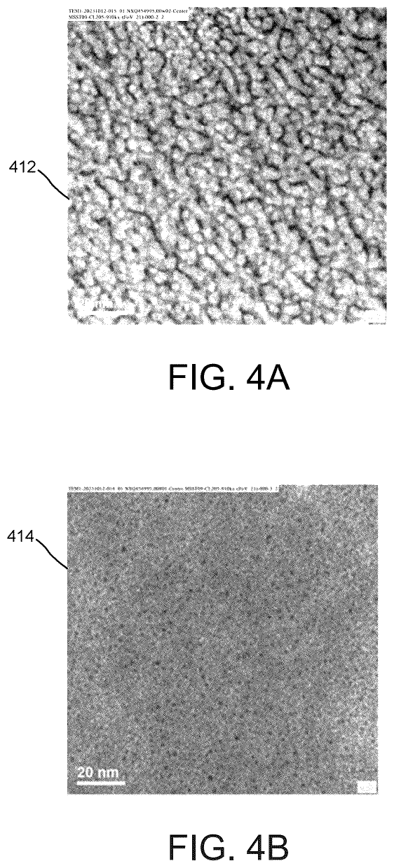

FIG. 4A is a diagram illustrating the film morphology of a film deposited using pure sputtering. FIG. 4B is a diagram illustrating the film morphology of a film deposited using pure sputtering plus RF sputtering in accordance with some embodiments. Since RF sputtering provides better plasma control over plasma parameters, such as ion density, electron temperature, and the like, this allows for more precise tuning of the deposition process. As a result, a balanced ratio of ions to atoms can promote denser film growth. Proper control of plasma parameters can minimize resputtering, where deposited atoms are re-sputtered back into the vacuum chamber, which would reduce the deposition rate and film density. In addition, RF sputtering often exhibits less target erosion compared to DC sputtering. This can lead to a more uniform and consistent deposition process, resulting in denser films.

As shown in FIGS. 4A and 4B, the film 414 is denser than the film 412, and the grain size of the film 414 is smaller than the grain size of the film 412. The film density of the film 412 is 6.9 g/cm³, whereas the film density of the film 412 is 6.9 g/cm³. In other words, the film density has been improved by about 10% by using the combination of DC sputtering and RF sputtering, instead of using pure DC sputtering.

Moreover, since the grain size is reduced, the coercive force (i.e., Hc) is reduced as well. Coercive force is a property of magnetic materials that measures the external magnetic field required to demagnetize a fully magnetized material. It is the strength of the magnetic field required to reduce the magnetization of a material to zero after it has been fully magnetized. Coercive force can be measured using a hysteresis loop, which is a plot of magnetization versus applied magnetic field. The coercive force is the magnitude of the magnetic field at which the magnetization crosses the x-axis.

Materials with a higher coercive force are more resistant to demagnetization. They retain their magnetization even in the presence of opposing magnetic fields. Materials with a lower coercive force are easier to demagnetize. They lose their magnetization more readily when exposed to opposing magnetic fields. Materials with low coercive force are used in applications where the magnetization needs to be easily reversed, such as in transformers and inductors. In the semiconductor space, materials with low coercive force, also known as soft magnetic materials, have several important applications. Soft magnetic materials are used in the magnetic heads of hard disk drives (HDDs) to read and write data. The low coercive force allows the heads to easily magnetize and demagnetize, enabling efficient data transfer. Similar to HDDs, soft magnetic materials are used in magnetic tape drives to read and write data. Soft magnetic materials are used in the inductors and transformers found in power supplies used in semiconductor manufacturing equipment. Their low coercive force helps to minimize energy losses and improve efficiency. Soft magnetic materials are also used in inductors and transformers for radio frequency (RF) applications, such as in RF power amplifiers and matching networks. Soft magnetic materials can also be used to shield sensitive semiconductor equipment from external magnetic fields, which can interfere with device performance and manufacturing processes. Additionally, soft magnetic materials are used in magnetic sensors for measuring position, speed, and other mechanical quantities. Their low coercive force allows for sensitive detection of magnetic fields.

Factors that impact the coercive force include grain size, crystal structure, impurities and defects, and magnetic anisotropy. As to grain size, it has been observed that the coercive force is approximately proportional to D⁶ (where D stands for the grain size) at the lower end. Therefore, the decreased grain size results in a lower coercive force. In one example, the coercive force is about 10 Oe (i.e., Oersted, which is equivalent to 1000/4π amperes per meter (A/m) in SI units) when the film is deposited using pure DC sputtering, whereas the coercive force is about 0.6 Oe when the film is deposited using a combination of DC sputtering and RF sputtering in accordance with the techniques disclosed herein.

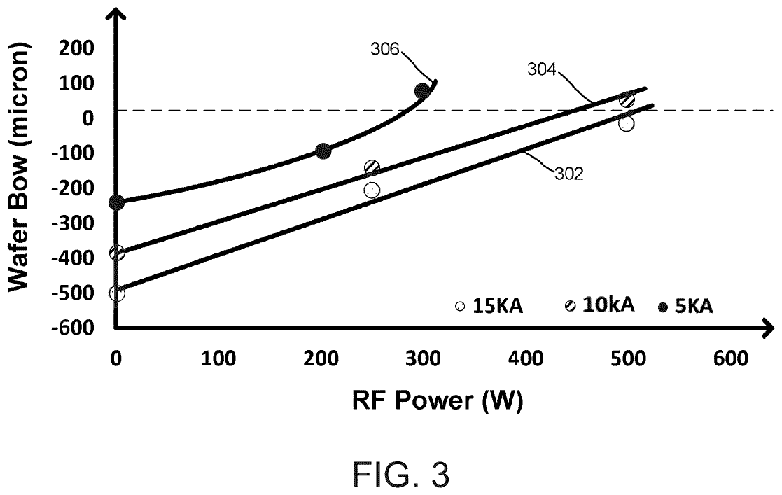

FIG. 3 is a diagram illustrating the substrate bow measures at different RF power in accordance with some embodiments. Thick films (e.g., with a thickness above 5,000 angstroms) deposited on the substrate 102 may result in substrate warpage (also referred to as “wafer bow”). Wafer bow is a phenomenon where a (silicon) wafer becomes warped or bent during the manufacturing process. This distortion can have significant implications for device performance and yield. Reasons for wafter bow include thin film deposition (e.g., by sputtering using a PVD system), thermal stress, ion implantation, chemical mechanical planarization (CMP), and etching. As to thin film deposition, the deposition of thin films with different thermal expansion coefficients than the substrate can cause stress and wafer bow. Because of this characteristic, the measure of wafer bow or substrate warpage can be used to characterize the intrinsic stress of the films. The larger the measure of wafer bow, the larger the stress of the film.

As shown in FIG. 3, three films with different thicknesses, namely 15,000 angstroms (curve 302), 10,000 angstroms (curve 304), and 5,000 angstroms (curve 306), are deposited using the PVD system 100 shown in FIG. 1. In the example shown in FIG. 3, if the RF power is zero (i.e., pure DC sputtering), the measures of wafer bow are relatively large. Specifically, the thicker the film, the larger the measure of wafer bow. As the RF power increases, the measure of wafer bow decreases. For example, the measure of wafer bow for the film with a thickness of 5,000 angstroms decreases to about zero when the RF power rises to about 300 W; the measure of wafer bow for the film with a thickness of 10,000 angstroms decreases to about zero when the RF power rises to about 500 W; the measure of wafer bow for the film with a thickness of 15,000 angstroms decreases to about zero when the RF power rises to about 500 W. Thus, the intrinsic stress of all these films (with a thickness of 15,000 angstroms, 10,000 angstroms, and 5,000 angstroms) decreases as the RF sputtering is introduced in addition to the DC sputtering and as the RF power increases. Thus, introducing RF sputtering with appropriate RF power in addition to DC sputtering can reduce stress because of the benefits of RF sputtering, as explained above. In the meantime, as discussed above with reference to FIG. 2, by fine-tuning the RF frequency, the deposition rate can be maintained as compared to pure DC sputtering.

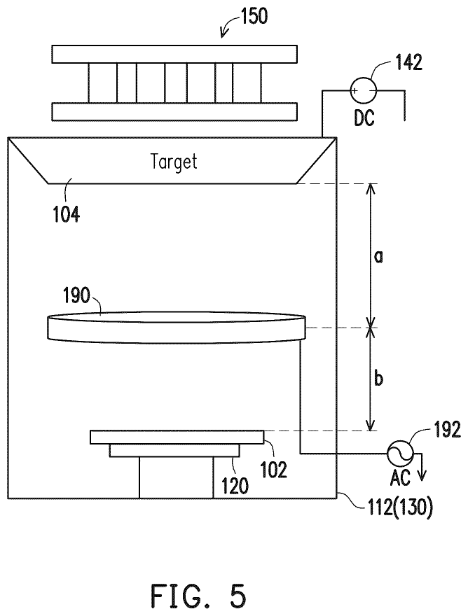

FIG. 5 is a diagram illustrating an example PVD system 500 according to some embodiments. The PVD system 500 shown in FIG. 5 is similar to the PVD system 100 shown in FIG. 1, and similar components are not repeated because of this. In the perspective view shown in FIG. 5, the RF coil 190 has a circular ring shape. The distance in the vertical direction between the RF coil 190 and the lower surface of the PVD target 104 is a, whereas the distance in the vertical direction between the RF coil 190 and the upper surface of the substrate 102 is b. It has been appreciated by Applicant that increasing the distance a can increase the deposition rate. In some embodiments, a is greater than 100 mm. In other embodiments, a is greater than 150 mm. In other embodiments, a is greater than 200 mm. In some embodiments, b is greater than 100 mm. In other embodiments, b is greater than 150 mm. In other embodiments, b is greater than 200 mm. In other words, the RF coil 190 is closer to the substrate 102 than to the PVD target 104. In some embodiments, a is greater than b. In other embodiments, the ratio of a to b is larger than 1.5.

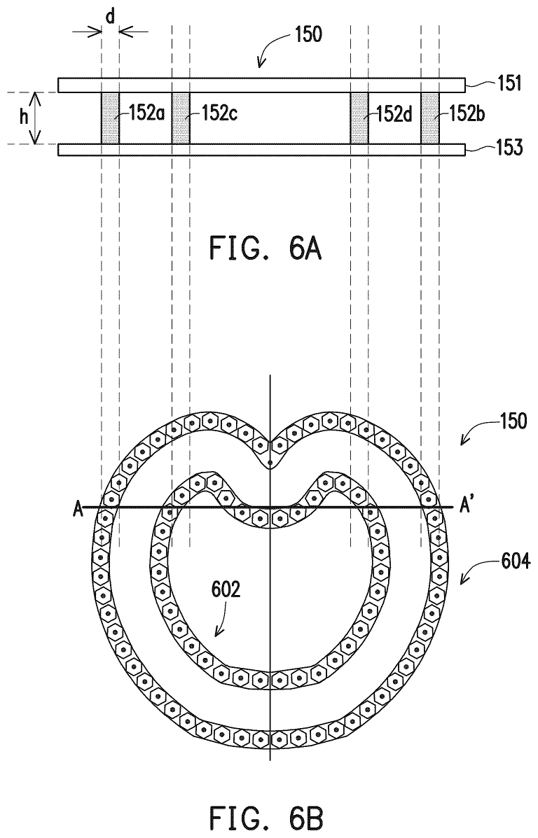

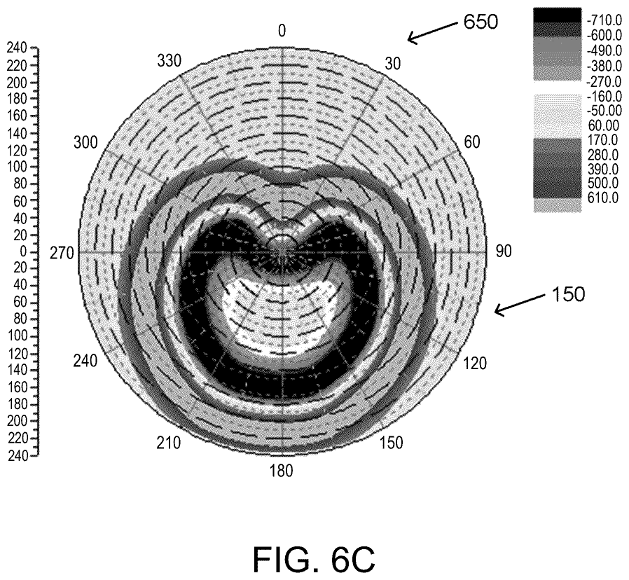

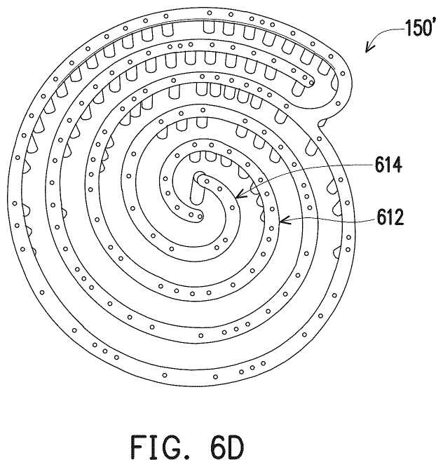

FIG. 6A is a cross-sectional diagram illustrating an example magnet assembly 150 in accordance with some embodiments. FIG. 6B is a diagram illustrating a top view of the example magnet assembly 150 shown in FIG. 6A in accordance with some embodiments. FIG. 6C is a diagram illustrating a simulation result of the example magnet assembly 150 shown in FIG. 6A in accordance with some embodiments. As explained above, a stronger magnet assembly 150 that produces a stronger magnetic field in the processing region or a plasma zone 114 can increase the deposition rate and reduce film stress.

In the example shown in FIG. 6A, the magnet assembly 150 includes a bottom support structure 153, a top support structure 151, and a number of magnetic columns (or “magnetic pillars”) 152 disposed between them. Each magnetic column 152 is characterized by a height h and a diameter d. In some embodiments, the height h is larger than 30 mm. In some embodiments, the diameter d is larger than 15 mm. The magnetic columns 152 include permanent magnets made of, for example, rare earth, high strength materials. The magnetic columns 152 are arranged in a substantially upright position with reference to the horizontal plane. The bottom support structure 153 and the top support structure 151 secure the magnetic columns 152 and enhance the stability of the magnet assembly 150. It should be understood that only one of the bottom support structure 153 and the top support structure 151 may be used in some embodiment as needed. One of ordinary skill in the art would recognize many variations, modifications, and alternatives.

FIG. 6A is the cross-section taken at A-A′ in FIG. 6B. As shown in FIG. 6B, the magnetic columns 152 can be divided into two branches (or groups), namely branch 602 and branch 604. Each branch is comprised of a number of magnetic columns 152. In the example shown in FIG. 6B, the branch 602 and the branch 604 are concentric, each having an “apple shape.” In some embodiments, the polarity (i.e., north pole or south pole) of neighboring magnetic columns 152 are the same. In some embodiments, the polarity (i.e., north pole or south pole) of neighboring magnetic columns 152 are opposite to each other. In some embodiments, the polarity (i.e., north pole or south pole) of neighboring magnetic columns 152 is a combination of the two situations discussed above. One of ordinary skill in the art would recognize many variations, modifications, and alternatives.

In order to produce a strong magnetic field, the magnet column density (i.e., the number of magnet columns 152 per square centimeter (cm⁻²) has been increased. In some embodiments, the magnet column density is equal to or greater than 0.05 cm⁻² (i.e., at least one magnet column 152 every twenty square centimeters). In other embodiments, the magnet column density is equal to or greater than 0.1 cm⁻². In other embodiments, the magnet column density is equal to or greater than 0.2 cm⁻².

In the example shown in FIG. 6C, the simulation result 650 shows that the magnetic field (measured by the magnetic flux density) has a high value (close to ±700 units) at the center of the magnet assembly 150. In some embodiments, the magnetic field strength at the surface (when measured at a place 1 mm from the surface) of the PVD target 104 is larger than 400 Gs (Gauss, 1 Gauss is equal to 10⁻⁴ Tesla). To put this in perspective, a conventional magnet assembly produces a magnetic field characterized by a magnetic field strength of about 200 Gs at the surface of the PVD target 104. In other words, the magnetic field strength is more than doubled by using the magnet assembly 15,0 characterized by a relatively high magnet column density, disclosed herein.

FIG. 6D is a diagram illustrating another example magnet assembly 150′ in accordance with some embodiments. In the embodiment shown in FIG. 6D, the magnet assembly 150′ includes a number of magnetic columns 152, which can be divided into two branches (or groups), namely branch 612 and branch 614. Each branch is comprised of a number of magnetic columns 152. In the example shown in FIG. 6D, each of the branch 612 and the branch 614 has a “spiral shape.” In some embodiments, the polarity (i.e., north pole or south pole) of neighboring magnetic columns 152 are the same. In some embodiments, the polarity (i.e., north pole or south pole) of neighboring magnetic columns 152 are opposite to each other. In some embodiments, the polarity (i.e., north pole or south pole) of neighboring magnetic columns 152 is a combination of the two situations discussed above. Similarly, each magnetic column 152 is characterized by a height h and a diameter d. In some embodiments, the height h is larger than 30 mm. In some embodiments, the diameter d is larger than 15 mm. Likewise, the magnet assembly 150′ may further include at least one of a bottom support structure and a top support structure. One of ordinary skill in the art would recognize many variations, modifications, and alternatives.

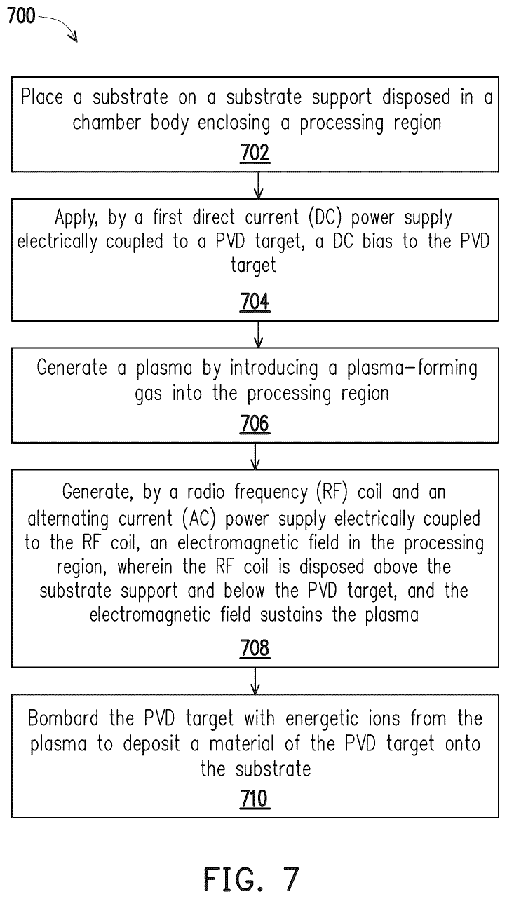

FIG. 7 is a flowchart illustrating an example method 700 for operating a PVD system in accordance with some embodiments. In the example shown in FIG. 7, the method 700 includes operations 702, 704, 706, 708, and 710. Additional operations may be performed. Also, it should be understood that the sequence of the various operations discussed above with reference to FIG. 7 is provided for illustrative purposes, and as such, other embodiments may utilize different sequences. These various sequences of operations are to be included within the scope of embodiments.

At operation 702, a substrate (e.g., the substrate 102 shown in FIG. 1) is placed on a substrate support (e.g., the substrate support 120 shown in FIG. 1) disposed in a chamber body enclosing a processing region (e.g., the processing region 114 shown in FIG. 1).

At operation 704, a DC bias is applied, by a first direct current (DC) power supply (e.g., the DC power supply 140 shown in FIG. 1) electrically coupled to a PVD target (e.g., the PVD target 104 shown in FIG. 1), to the PVD target.

At operation 706, a plasma is generated by introducing a plasma-forming gas into the processing region.

At operation 708, an electromagnetic field in the processing region is generated by a radio frequency (RF) coil (e.g., the RF coil 190 shown in FIG. 1) and an alternating current (AC) power supply (e.g., the AC power supply 192 shown in FIG. 1) electrically coupled to the RF coil. The RF coil is disposed above the substrate support and below the PVD target. The electromagnetic field sustains the plasma. In some embodiments, an RF frequency of RF power delivered to the RF coil is equal to or higher than 8 MHz.

At operation 710, the PVD target is bombarded with energetic ions from the plasma to deposit a material of the PVD target onto the substrate.

Additional operation(s) may be included. For example, a magnetic field is projected, by a magnet assembly disposed above the PVD target, in the processing region. In some embodiments, a surface magnetic field strength of the magnetic field is equal to or larger than 400 Gs.

In accordance with some aspects of the disclosure, a physical vapor deposition (PVD) system is provided. The PVD system includes: a chamber body enclosing a processing region; a substrate support disposed in the chamber body and configured to support a substrate; a PVD target disposed in the chamber body and over the substrate support; a radio frequency (RF) coil disposed in the chamber body, the RF coil being above the substrate support and below the PVD target; a first direct current (DC) power supply electrically coupled to the PVD target to provide a DC bias to the PVD target; and an alternating current (AC) power supply electrically coupled to the RF coil, wherein the AC power supply delivers RF power to the RF coil to generate an electromagnetic field in the processing region.

In accordance with some aspects of the disclosure, a method for operating a physical vapor deposition (PVD) system is provided. The method comprises the following steps: placing a substrate on a substrate support disposed in a chamber body enclosing a processing region; applying, by a first direct current (DC) power supply electrically coupled to a PVD target, to provide a DC bias to the PVD target; generating a plasma by introducing a plasma-forming gas into the processing region; generating, by a radio frequency (RF) coil and an alternating current (AC) power supply electrically coupled to the RF coil, an electromagnetic field in the processing region, wherein the RF coil is disposed above the substrate support and below the PVD target, and the electromagnetic field sustains the plasma; and bombarding the PVD target with energetic ions from the plasma to deposit a material of the PVD target onto the substrate.

In accordance with some aspects of the disclosure, a physical vapor deposition (PVD) system is provided. The PVD system comprises: a chamber body enclosing a processing region; a substrate support disposed in the chamber body; a PVD target disposed in the chamber body and over the substrate support; a magnet assembly disposed above the PVD target and configured to project a magnetic field in the processing region, wherein a surface magnetic field strength of the magnetic field is equal to or larger than 400 G; and a first direct current (DC) power supply electrically coupled to the PVD target to provide a DC bias to the PVD target.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A physical vapor deposition (PVD) system comprising:
a chamber body enclosing a processing region;
a substrate support disposed in the chamber body and configured to support a substrate;
a PVD target disposed in the chamber body and over the substrate support;
a radio frequency (RF) coil disposed in the chamber body, the RF coil being above the substrate support and below the PVD target;
a first direct current (DC) power supply electrically coupled to the PVD target to provide a DC bias to the PVD target; and
an alternating current (AC) power supply electrically coupled to the RF coil, wherein the AC power supply delivers RF power to the RF coil to generate an electromagnetic field in the processing region.

2. The PVD system of claim 1, wherein an RF frequency of the RF power is equal to or higher than 8 MHz.

3. The PVD system of claim 1, wherein an RF frequency of the RF power is between 13.5 MHz and 100 MHz.

4. The PVD system of claim 1, wherein an RF frequency of the RF power is between 13.5 MHz and 50 MHz.

5. The PVD system of claim 1, wherein the RF coil is a planar RF coil place parallel to the PVD target.

6. The PVD system of claim 5, wherein the RF coil is characterized by a ring shape.

7. The PVD system of claim 1, wherein a first distance between the RF coil and a lower surface of the PVD target is greater than 100 mm.

8. The PVD system of claim 1, wherein a second distance between the RF coil and an upper surface of a substrate disposed on the substrate support is greater than 100 mm.

9. The PVD system of claim 1, wherein a first distance between the RF coil and a lower surface of the PVD target is greater than a second distance between the RF coil and an upper surface of a substrate disposed on the substrate support.

10. The PVD system of claim 1, further comprising:
a magnet assembly disposed above the PVD target and configured to project a magnetic field in the processing region.

11. The PVD system of claim 10, wherein the magnet assembly comprises:
at least one of a bottom support structure and a top support structure; and
a plurality of magnetic columns secured to the at least one of the bottom support structure and the top support structure.

12. The PVD system of claim 11, wherein a density of the plurality of magnetic columns is equal to or greater than 0.05 cm⁻².

13. The PVD system of claim 10, wherein a surface magnetic field strength of the magnetic field is equal to or larger than 400 Gs.

14. The PVD system of claim 1, further comprising:
a second DC power supply electrically coupled to the substrate support to provide a second DC bias to the substrate support.

15. A method for operating a physical vapor deposition (PVD) system, the method comprising:
placing a substrate on a substrate support disposed in a chamber body enclosing a processing region;
applying, by a first direct current (DC) power supply electrically coupled to a PVD target, to provide a DC bias to the PVD target;
generating a plasma by introducing a plasma-forming gas into the processing region;
generating, by a radio frequency (RF) coil and an alternating current (AC) power supply electrically coupled to the RF coil, an electromagnetic field in the processing region, wherein the RF coil is disposed above the substrate support and below the PVD target, and the electromagnetic field sustains the plasma; and
bombarding the PVD target with energetic ions from the plasma to deposit a material of the PVD target onto the substrate.

16. The method of claim 15, wherein an RF frequency of RF power delivered to the RF coil is equal to or higher than 8 MHz.

17. The method of claim 15, further comprising:
projecting, by a magnet assembly disposed above the PVD target, a magnetic field in the processing region.

18. The method of claim 15, wherein a surface magnetic field strength of the magnetic field is equal to or larger than 400 Gs.

19. A physical vapor deposition (PVD) system comprising:
a chamber body enclosing a processing region;
a substrate support disposed in the chamber body;
a PVD target disposed in the chamber body and over the substrate support;
a magnet assembly disposed above the PVD target and configured to project a magnetic field in the processing region, wherein a surface magnetic field strength of the magnetic field is equal to or larger than 400 G; and
a first direct current (DC) power supply electrically coupled to the PVD target to provide a DC bias to the PVD target.

20. The PVD system of claim 19, further comprising:
a radio frequency (RF) coil disposed in the chamber body, the RF coil being above the substrate support and below the PVD target; and
an alternating current (AC) power supply electrically coupled to the RF coil, wherein the AC power supply delivers RF power to the RF coil to generate an electromagnetic field in the processing region.
